(19) United States
(12) Patent Application Publication
(10) Pub. No.: US 2010/0289104 A1
(43) Pub. Date: Nov. 18, 2010

(54) PHOTOSENSOR PACKAGE

(75) Inventors: Jeong Seok RA, Chungcheongbuk-Do (KR); Jin Kwan KIM, Chungcheongbuk-Do (KR); Hui Tae KIM, Chungcheongbuk-Do (KR); Gi Tae LIM, Gyeongsangbuk-Do (KR)

Correspondence Address: HOSOON LEE, 9600 SW OAK ST. SUITE 525, TIGARD, OR, 97223, US

(73) Assignee: OPTOPAC CO., LTD., Chungcheongbuk-Do (KR)

(21) Appl. No.: 12/779,943

(22) Filed: May 13, 2010

(30) Foreign Application Priority Data
May 14, 2009 (KR) 10-2009-0042145
Apr. 21, 2010 (KR) 10-2010-0036979

(51) Int. Cl. H01L 31/02

(52) U.S. Cl. 257/459; 257/E31.113

(57) ABSTRACT

A photosensor package includes a substrate assembly, a photosensor chip mounted at the substrate assembly, a solder ball to electrically connect the photosensor chip, the substrate assembly and a printed circuit board, and a passive device mounted at the substrate assembly.

Since the passive device is disposed on the substrate assembly of the photosensor package, it is possible to reduce the size of the printed circuit board compared to the convention technology where the passive device is disposed on the print circuit board. Furthermore, since it is possible to reduce a distance between the photosensor chip and the passive device, the electrical properties are also improved, and the number of processes may be reduced.

### CROSS-REFERENCE TO RELATED APPLICATION

This application claims priority to Korean Patent Application Nos. 10-2009-0042145 filed on May 14, 2009 and 10-2010-0036979 filed on Apr. 21, 2010, and all the benefits accruing therefrom under 35 U.S.C. §119, the contents of which are incorporated by reference in their entirety.

### BACKGROUND

The present disclosure relates to a photosensor package, and more particularly, to a photosensor package including a passive device mounted at a substrate assembly.

A photosensor is a semiconductor device having a function of photographing an image of an object, and thus a market of the photosensor is swelling nowadays as the photosensor is mounted at a mobile phone as well as in a digital camera or a camcorder.

The photosensor is mounted at the mobile phone, the digital camera and the camcorder in the form of a camera module. The camera module includes a lens, a holder, an infrared (IR) filter, a photosensor and a printed circuit board (PCB). The lens images an object; the image is condensed on the photosensor through the IR filter; and the photosensor converts a light signal of the image to an electrical signal to thereby photograph the image.

In general, the photosensor includes a pixel region in its central portion and bonding pads disposed in its peripheral portion. The pixel region senses images, and the bonding pads transmit or receive electrical signals of images taken at pixels or other signals, or supply power. The photosensor may use a chip on board (COB) scheme where the photosensor is directly mounted at the camera module in a state of a bare chip, or a chip scale package (CSP) scheme where a photosensor chip is packaged and then mounted at the camera module. When using the CSP scheme, it is possible to prevent mist particles or moisture from flowing into an image sensing region generated in the CSP scheme.

Meanwhile, the photosensor package is sold as one component to fabricate the camera module or assembled into the camera module in a different fabricating line. That is, the photosensor package is fabricated as a separate component, moved to a different fabricating line or factory, and then mounted at a printed circuit board (PCB). After that, a flexible printed circuit (FPC) is attached, and then a holder and the lens housing are mounted at the PCB, thereby completing the camera module.

In a process where the photosensor package is mounted at the PCB, a passive device such as a resistor, an inductor and a capacitor is mounted at another region of the PCB and thus electrically connected to the photosensor package. As described above, when the passive device is mounted at the PCB in addition to the photosensor package, the size of the PCB increases. Furthermore, when the passive device is mounted at the PCB, a distance between the passive device and the photosensor package becomes far off, and thus a path of an electrical signal becomes longer. As a result, an electrical property is deteriorated. Moreover, since the process of installing the photosensor package is performed separately from the process of installing the passive device, the fabricating process becomes complicated.

### SUMMARY

The present disclosure provides a photosensor package including a passive device.

The present disclosure provides a photosensor package capable of overcoming the above problems by building a passive device on a transparent substrate where a photosensor chip is mounted.

The present disclosure provides a photosensor package formed by etching a certain region of a transparent substrate where a photosensor chip is mounted so as to form a recess, and by mounting a passive device in the recess.

In accordance with an exemplary embodiment, a photosensor package includes: a substrate assembly; a photosensor chip mounted at the substrate assembly; a solder ball to electrically connect the photosensor chip, the substrate assembly and a printed circuit board; and a passive device mounted at the substrate assembly.

A thickness of one portion of the substrate assembly may be smaller than those of other portions.

The photosensor chip may be mounted at the portion whose thickness is smaller.

The passive device may be disposed on the outside of a pixel region of the photosensor chip.

The passive device may be mounted at one side of the substrate assembly on which the photosensor chip is disposed.

The passive device may be disposed between solder balls.

The passive device may be disposed on the outside of the solder ball.

The passive device may be mounted at the other side of the substrate assembly on which the photosensor chip is not disposed.

The passive device may be electrically connected to one side of the substrate assembly through a penetration hole which penetrates a portion of the substrate assembly and is filled with a conductive material. In accordance with an exemplary embodiment,

In accordance with another exemplary embodiment, a photosensor package includes: a substrate assembly including a transparent substrate; a photosensor chip mounted at the substrate assembly; a plurality of solder balls to electrically connect the photosensor chip, the substrate assembly and a printed circuit board; and a passive device mounted in the transparent substrate of the substrate assembly.

A thickness of one portion of the substrate assembly may be smaller than those of other portions, and the photosensor chip may be mounted at the portion whose thickness is smaller.

The passive device may be mounted at the outside of a pixel region of the photosensor chip.

The passive device may be mounted in a recess formed by etching the transparent substrate at a region corresponding to at least one of the solder balls. The passive device may be mounted in a recess formed by etching the transparent substrate at a region between the solder ball and the photosensor chip. The passive device may be mounted in a recess formed by etching the transparent substrate at the outside of the solder ball.

The passive device may be electrically connected through a metal line formed on a surface of the transparent substrate.

The passive device may be electrically connected to a surface of the transparent substrate through a through hole that vertically passes through a region of the transparent substrate, and a conductive material is buried in the through hole.

### BRIEF DESCRIPTION OF THE DRAWINGS

Exemplary embodiments can be understood in more detail from the following description taken in conjunction with the accompanying drawings, in which:

FIG. 1 is a plane view of a photosensor package in accordance with a first exemplary embodiment of the present invention;

FIGS. 2 and 3 are cross-sectional views taken along a line A-A′ and a line B-B′ of FIG. 1, respectively;

FIG. 4 is a plane view of a photosensor package in accordance with a second exemplary embodiment of the present invention;

FIG. 5 is a cross-sectional view taken along a line C-C′ of FIG. 4;

FIG. 6 is a cross-sectional view of a photosensor package in accordance with a third exemplary embodiment of the present invention;

FIG. 7 is a cross-sectional view of a photosensor package in accordance with a fourth exemplary embodiment of the present invention;

FIG. 8 is a plane view of a photosensor package in accordance with a fifth exemplary embodiment of the present invention;

FIGS. 9 and 10 are cross-sectional views taken along a line A-A′ and a line B-B′ of FIG. 8, respectively;

FIGS. 11 to 13 are plane views of photosensor packages in accordance with modified examples of the fifth exemplary embodiment of the present invention;

FIG. 14 is a cross-sectional view of a photosensor package in accordance with a sixth exemplary embodiment of the present invention;

FIGS. 15 to 17 are cross-sectional views illustrating a method of mounting a passive device in accordance with the fifth exemplary embodiment of the present invention in a transparent substrate; and

FIG. 18 is a cross-sectional view of a substrate assembly in which a passive device is mounted, in accordance with a seventh exemplary embodiment of the present invention.

### DETAILED DESCRIPTION OF EXEMPLARY EMBODIMENTS

Hereinafter, specific exemplary embodiments will be described in detail with reference to the accompanying drawings. The present invention may, however, be embodied in different forms and should not be construed as limited to the exemplary embodiments set forth herein. Rather, these exemplary embodiments are provided so that this disclosure will be thorough and complete, and will fully convey the scope of the present invention to those skilled in the art. Furthermore, the same or like reference numerals represent the same or like constituent elements, although they appear in different exemplary embodiments or drawings of the present invention.

The drawings are not necessarily to scale and in some instances, proportions may have been exaggerated in order to clearly illustrate features of the exemplary embodiments. When a first layer is referred to as being “on” a second layer or “on” a substrate, it not only refers to a case where the first layer is formed directly on the second layer or the substrate but also a case where a third layer exists between the first layer and the second layer or the substrate.

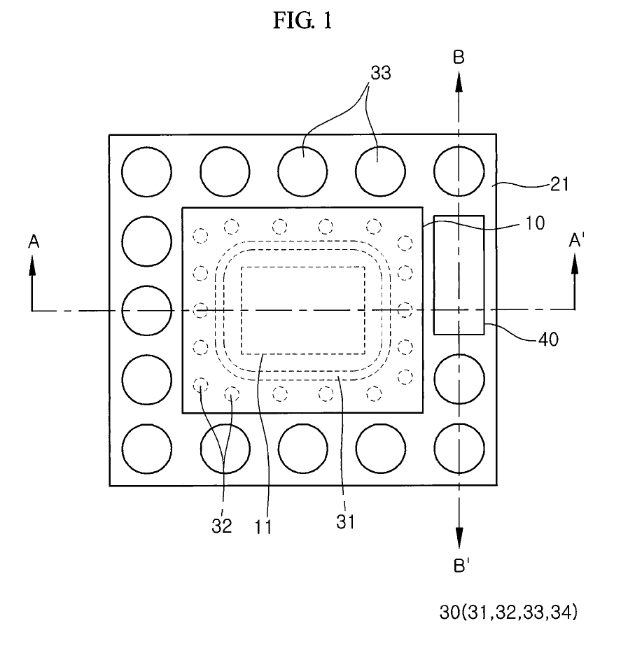

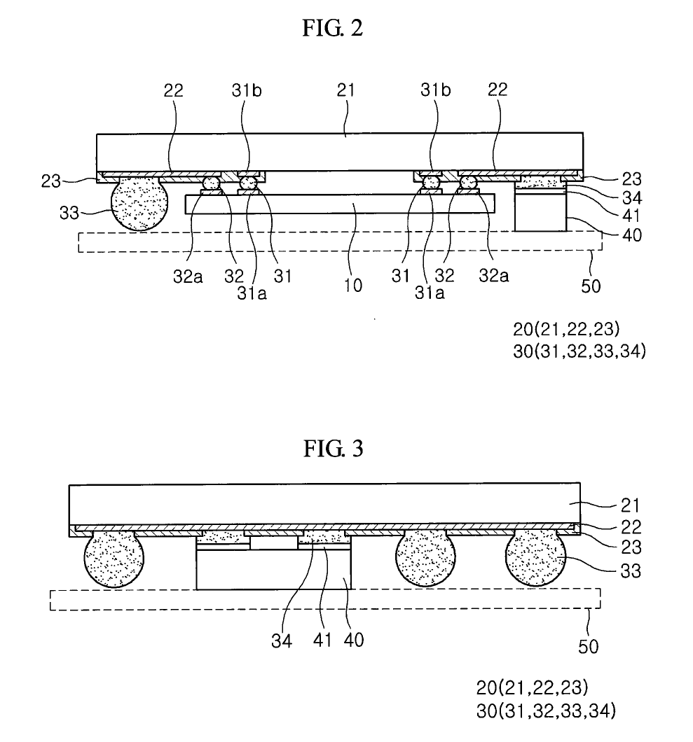

FIG. 1 is a plane view of a photosensor package in accordance with a first exemplary embodiment of the present invention. FIGS. 2 and 3 are cross-sectional views taken along a line A-A′ and a line B-B′ of FIG. 1, respectively.

Referring to FIGS. 1 to 3, the photosensor package in accordance with the first exemplary embodiment includes a photosensor chip 10 for sensing an image, a substrate assembly 20 disposed to face the photosensor chip 10 and electrically connected to the photosensor chip 10, a solder part 30 for electrically connecting the photosensor chip 10, the substrate assembly 20 and a printed circuit board 50, and a passive device 40 mounted at the outside of a pixel region 11 on the substrate assembly 20.

The photosensor chip 10 includes the pixel region 11 disposed at its central portion to sense images, and a terminal region (not shown) disposed at its peripheral portion to transmit electrical signals of the images photographed in the pixel region 11, to transceive other signals, or to supply the power. The pixel region 11 may include a plurality of photodiodes for converting the light to the electrical signals, color filters of three colors, i.e., red, green and blue, disposed on the photodiodes to classify colors, and a micro lens, disposed on the color filters, for focusing the light on the photodiodes and thus enhancing the sensibility. The photodiodes, the color filters and the micro lens may be stacked with each other.

The substrate assembly 20 includes a transparent substrate 21, a metal line 22 selectively formed on one side of the transparent substrate 21 where the photosensor chip 10 is installed, and an insulation layer 23 formed on the metal line 22 to insulate the metal line 22. The transparent substrate 21 may be formed in a plate shape having a certain thickness with a transparent material such as glass and plastic. An optical material may be coated on one side of the transparent substrate 21 where the metal line 22 is formed or the other side of the transparent substrate 21 where the metal line 22 is not formed, thereby performing filtering and improving the sensibility of the light in a desired wavelength band. For instance, an infrared (IR) cut-off film (not shown) or an IR cut-off filter (not shown) for transmitting or blocking the light in a certain wavelength band is coated on the other side of the transparent substrate 21 where the light enters. The metal line 22 is formed on one side of the transparent substrate 21 and in an outside region surrounding a region corresponding to the pixel region 11. The metal line 22 may be patterned using a printing process or patterned through photographing and etching processes after depositing a metallic material. Moreover, the insulation layer 23 is formed on the metal line 22 to expose a certain portion of the metal line 22. That is, the certain portion of the metal line 22 that is connected to a printed circuit board and the photosensor chip 10 is exposed by the insulation layer 23. The insulation layer 23 may be also patterned through the printing process or patterned through the photographing and etching processes after depositing an insulation material.

The solder part 30 includes a solder sealing ring 31 for preventing an alien substance from flowing into a sealing region including the pixel region 11 of the photosensor chip 10, a plurality of flip chip solder joints 32 for electrically connecting the photosensor chip 10 and the substrate assembly 20, a plurality of solder balls 33 for electrically connecting the substrate assembly 20 and the printed circuit board 50, and a connection solder 34 for electrically connecting the substrate assembly 20 and the passive device 40. The solder sealing ring 31 is disposed to surround the sealing region including the pixel region 11 of the photosensor chip 10 between the photosensor chip 10 and the substrate assembly 20 and prevents an alien substance from flowing into a space between the substrate assembly 20 and the photosensor chip 10. Solder sealing ring pads 31a and 31b are formed on a certain portion of the transparent substrate 21 and a certain portion of the photosensor chip 10 to form the solder sealing ring 31. Herein, the insulation layer 23 may be formed on the solder sealing ring pad 31b to partially expose the solder sealing ring pad 31b. The solder sealing ring 31 may have any shape capable of packaging the sealing region. For instance, the solder sealing ring 31 may have various shapes such as a closed loop shape and an unclosed loop shape having certain width and length and including an air path. Furthermore, the solder sealing ring 31 may include a main-solder sealing ring having an unclosed loop shape and a certain width, and one or more sub-solder sealing rings having a preset width around an unclosed portion of the main-solder sealing ring. The plurality of flip chip solder joints 32 is disposed between the photosensor chip 10 and the substrate assembly 20 on the outer side of the solder sealing ring 31. A flip chip solder joint pad 32a is formed in a certain region on the photosensor chip 10 to form the flip chip solder joint 32, and the flip chip solder joint 32 is disposed between the flip chip solder joint pad 32a on the photosensor chip 10 and the metal line 22 of the substrate assembly 20. The plurality of solder balls 33 is bonded onto the metal line 22 of the substrate assembly 20 on the outer side of the photosensor chip 10, thereby electrically connecting the substrate assembly 20 and the printed circuit board 50. The connection solder 34 is formed between the metal line 22 of the substrate assembly 20 and a connection pad 41 of the passive device 40. Herein, the plurality of solder balls 33 is formed at equal intervals along an outer line of the transparent substrate 21 having, e.g., a tetragonal shape. At least one of the solder balls 33 is removed, and at least one passive device 40 may be embodied instead of the removed solder ball.

The passive device 40 may include one or more of a decoupling capacitor, an inductor, a resistor and a filter and acts a part of removing noises of signals transmitted between the printed circuit board 50 and the photosensor chip 10. The passive device 40 is disposed on the substrate assembly 20 and mounted at one side of the transparent substrate 21 to be connected to a certain region of the metal line 22 exposed by the insulation layer 23. For instance, the passive device 40 and the solder ball 33 may be disposed on the same axis. That is, the passive device 40 is mounted at the location of at least one of the plurality of solder balls 33 formed on one side of the transparent substrate 21 to surround the photosensor chip 10, so that the passive device 40 act as the solder ball 33 to electrically connect the photosensor chip 10 and the printed circuit board 50. At this time, the connection solder 34 may be formed on the metal line 22 to build the passive device 40, and the connection pad 41 may be formed on the passive device 40. Therefore, the passive device 40 is connected between the metal line 22 of the substrate assembly 20 and a pad (not shown) of the printed circuit board 50. As illustrated in drawings, the passive device 40 may be mounted at the location where two adjacent solder balls 33 are removed or in the location where one solder ball 33 is removed. Moreover, each of two or more passive devices may be mounted at the location where at least one solder ball 33 is removed.

Meanwhile, the printed circuit board 50 may be connected to the solder ball 33 by the connection pad, and driving voltage and current from the outside are supplied to the photosensor chip 10 through the substrate assembly 20 since circuit patterns are printed on the printed circuit board 50. The printed circuit board 50 may include various boards such as a one-layer or multi-layer printed circuit board, a metallic printed circuit board, and a flexible printed circuit that are capable of supplying the driving voltage and current from the outside to the photosensor chip 10.

As described above, the photosensor package in accordance with the first exemplary embodiment of the present invention includes the passive device 40 mounted at the transparent substrate 21 of the substrate assembly 20, wherein the passive device 40 and the solder ball 33 are mounted at the same axis. Therefore, it is possible to reduce the size of the printed circuit board 50 compared to the conventional technology where the photosensor package and the passive device are mounted at the print circuit board, and thus it is also possible to reduce the size of the camera module. Moreover, according to the conventional technology, a signal path is extended by a long distance between the photosensor chip 10 and the passive device 40, and thus its electrical properties are deteriorated as noises flow into signals. However, since the passive device 40 is mounted at the substrate assembly 20 and disposed adjacent to the photosensor chip 10 in the inventive photosensor package, the signal path is shortened, and thus the electrical properties of the camera module are improved.

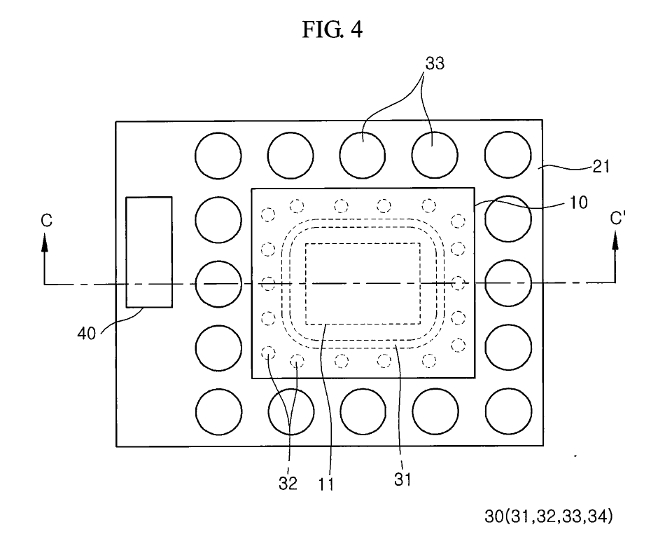

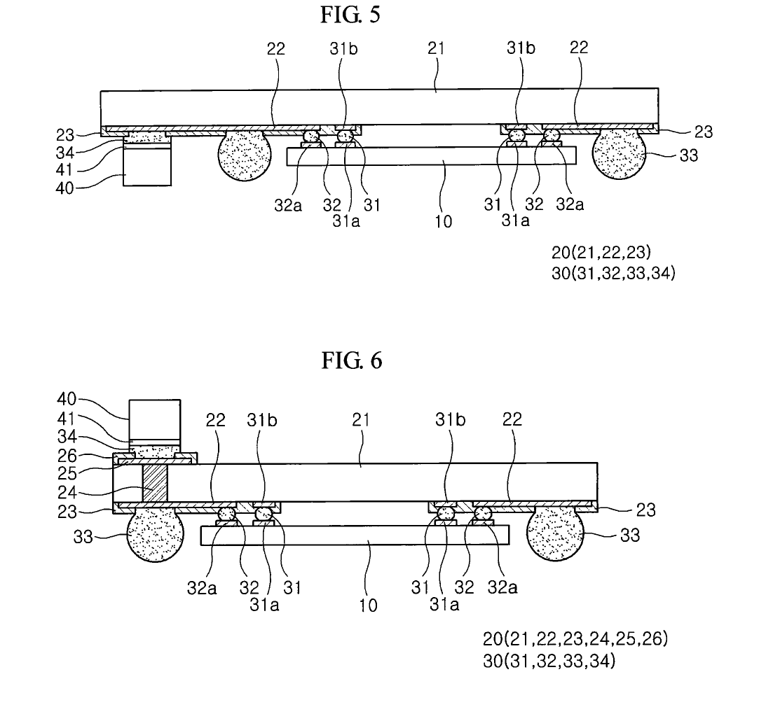

FIG. 4 is a plane view of a photosensor package in accordance with a second exemplary embodiment of the present invention, and FIG. 5 is a cross-sectional view taken along a line C-C′ of FIG. 4.

Referring to FIGS. 4 and 5, the photosensor package in accordance with the second exemplary embodiment includes a passive device 40 built under a transparent substrate 21 on the outside of a solder ball 33. That is, a plurality of solder balls 33 are disposed under the transparent substrate 21 to surround a photosensor chip 10, and the passive device 40 is built under the transparent substrate 21 on the outside of the solder ball 33 as being apart from the solder ball 33. Therefore, an insulation layer 23 is formed to selectively expose a metal line 22 on the outer side of the transparent substrate 21.

As shown in the above second exemplary embodiment, when building the passive device 40 on the outside of the solder ball 33 of the transparent substrate 21, the size of the transparent substrate 21 should be greater than that of the transparent substrate 21 of the first exemplary embodiment. That is, the size of the transparent substrate 21 is increased depending on an area of the metal line 22 and that of the passive device 40. However, although the size of the transparent substrate 21 becomes greater than that of the first exemplary embodiment, it is possible to reduce the size of a printed circuit board without increasing the size of a camera module. As a result, it is possible to further reduce the size of the camera module compared to the conventional technology.

FIG. 6 is a cross-sectional view of a photosensor package in accordance with a third exemplary embodiment of the present invention.

Referring to FIG. 6, the photosensor package in accordance with the third exemplary embodiment includes a passive device 40 mounted at a transparent substrate 21. That is, the passive device 40 is disposed on the transparent substrate 21 on the outside of a pixel region, e.g., on a portion of the transparent substrate 21 corresponding to one of a plurality of solder balls 33. The passive device 40 is electrically connected to a metal line 22 under the transparent substrate 21. For this purpose, a penetration hole 24 is formed to penetrate upper and lower portions in a certain region of the transparent substrate 21 and to include a conductive material therein; an upper line 25 is formed on the transparent substrate 21 above the penetration hole 24; and an insulation layer 26 is formed to protect and selectively expose the upper line 25. Furthermore, the passive device 40 is connected to the upper line 25 through a connection pad 41 and a connection solder 34. As a result, the passive device 40 is electrically connected to the metal line 22 under the transparent substrate 21 through the upper line 25 and the penetration hole 24 in which the conductive material is buried. Through this kind of scheme, a plurality of passive devices 40 is formed on the transparent substrate 21, and thus the size of a camera module can be reduced.

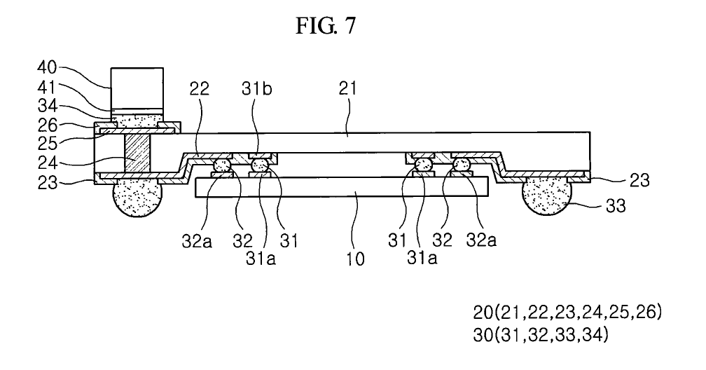

FIG. 7 is a cross-sectional view of a photosensor package in accordance with a fourth exemplary embodiment of the present invention.

Referring to FIG. 7, the photosensor package in accordance with the fourth exemplary embodiment includes a photosensor chip 10 disposed in a certain region under a transparent substrate 21, preferably, on a central portion of the transparent substrate 21, and a passive device 40 disposed on the transparent substrate 21, wherein the central portion has a smaller thickness compared to other portions. The thickness of the central portion of the transparent substrate 21 can be reduced through dry or wet etching. Herein, the step height between the etched portion and the un-etched portion may be steep or gentle. Meanwhile, the passive device 40 is mounted at the transparent substrate 21 on the outside of a pixel region, e.g., a portion of the transparent substrate 21 corresponding to a solder ball 33 to penetrate an upper and a lower portions of a certain region of the transparent substrate 21 and an upper line 25 on the transparent substrate 21. As a result, the passive device 40 is connected with an underlying metal line 22 through a penetration hole 24 where a conductive material is buried.

As shown in the fourth exemplary embodiment of the present invention, since the photosensor chip 10 is mounted at the central region whose thickness is smaller than that of a peripheral region, it is possible to reduce a thickness of the photosensor package and that of the camera module. Moreover, the size of the solder ball 33 is determined depending on the thickness of the photosensor chip 10. Therefore, the size of the solder ball 33 may be smaller since the photosensor chip 10 is disposed in the central region of the transparent substrate 21. As a result, the size of the photosensor package may be also reduced.

In the meantime, the disposition of the photosensor chip 10 in the central region under the transparent substrate 21 described in the fourth exemplary embodiment is applicable to the first and second exemplary embodiments. That is, the photosensor chip 10 may be mounted at the central region under the transparent substrate 21, and the passive device 40 may be mounted at the outside of the solder ball 33 as being apart from the solder ball 33 or on the same axis as that of the solder ball 33 under the transparent substrate 21.

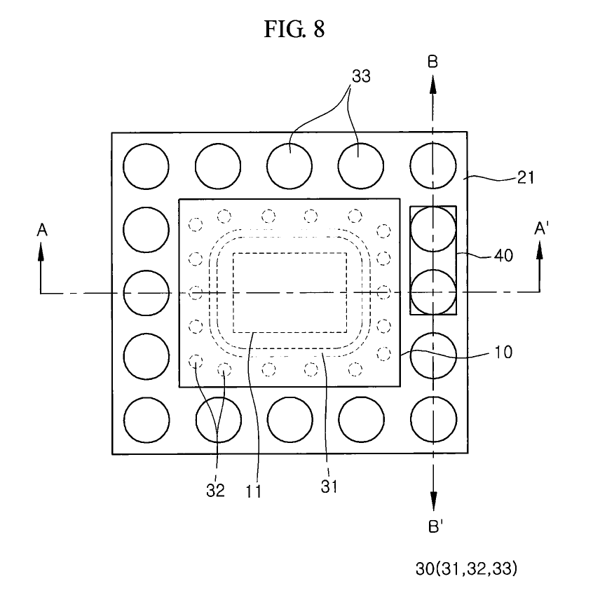

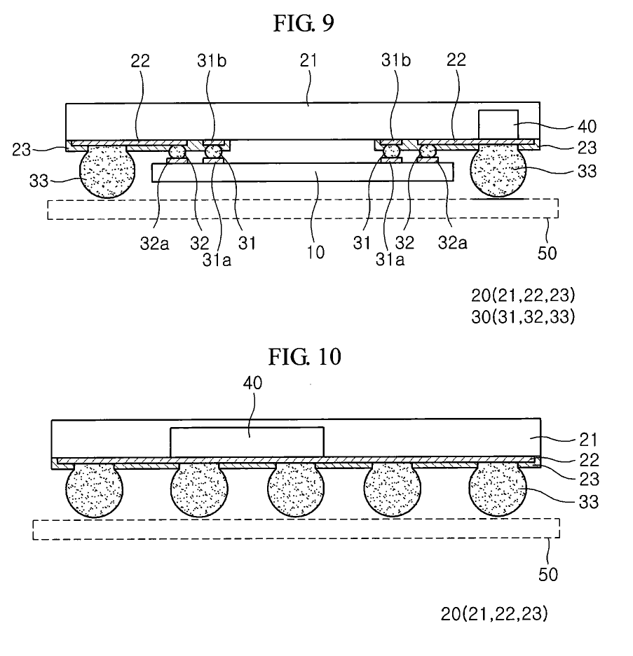

FIG. 8 is a plane view of a photosensor package in accordance with a fifth exemplary embodiment of the present invention. FIGS. 9 and 10 are cross-sectional views taken along a line A-A′ and a line B-B′ of FIG. 8, respectively.

Referring to FIGS. 8 to 10, the photosensor package in accordance with the fifth exemplary embodiment includes a photosensor chip 10 for sensing an image, a substrate assembly 20 disposed to face the photosensor chip 10 and electrically connected to the photosensor chip 10, a solder part 30 for electrically connecting the photosensor chip 10, the substrate assembly 20 and a printed circuit board 50, and a passive device 40 buried and mounted in a transparent substrate 21 of the substrate assembly 20. The fifth exemplary embodiment is different from the first exemplary embodiment in that the passive device 40 is mounted in the transparent substrate 21 of the substrate assembly 20, which will be principally described.

The passive device 40 is mounted in the transparent substrate 21 of the substrate assembly 20. That is, a recess having a certain shape is formed in a certain region of the transparent substrate 21, and then, the passive device 40 is mounted in the recess, and an insulating material such as polymer is buried in the rest region of the recess. For example, the passive device 40 and solder balls 33 may be coaxially disposed. That is, the recess is formed at a position where at least one of the solder balls 33 disposed on a surface of the transparent substrate 21 to surround the photosensor chip 10 is formed, and the passive device 40 is mounted in the recess, so as to reduce the area in which the passive device 40 is mounted. For example, the passive device 40 may be mounted in a region corresponding to the two solder balls 33. To this end, a connection pad (not shown) may be formed on a metal line 22 and the passive device 40.

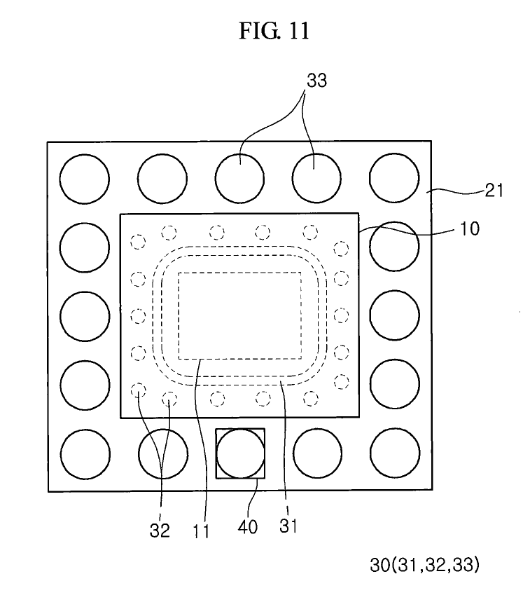

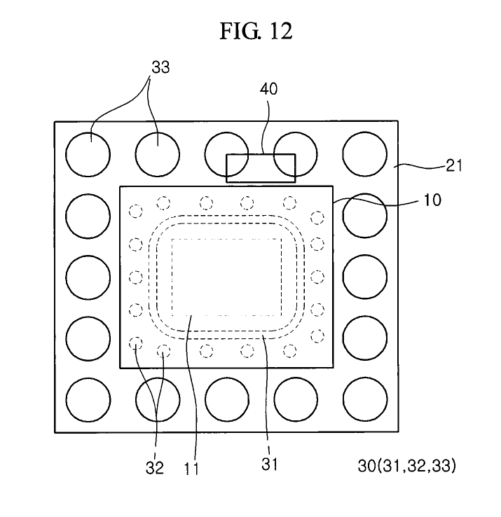

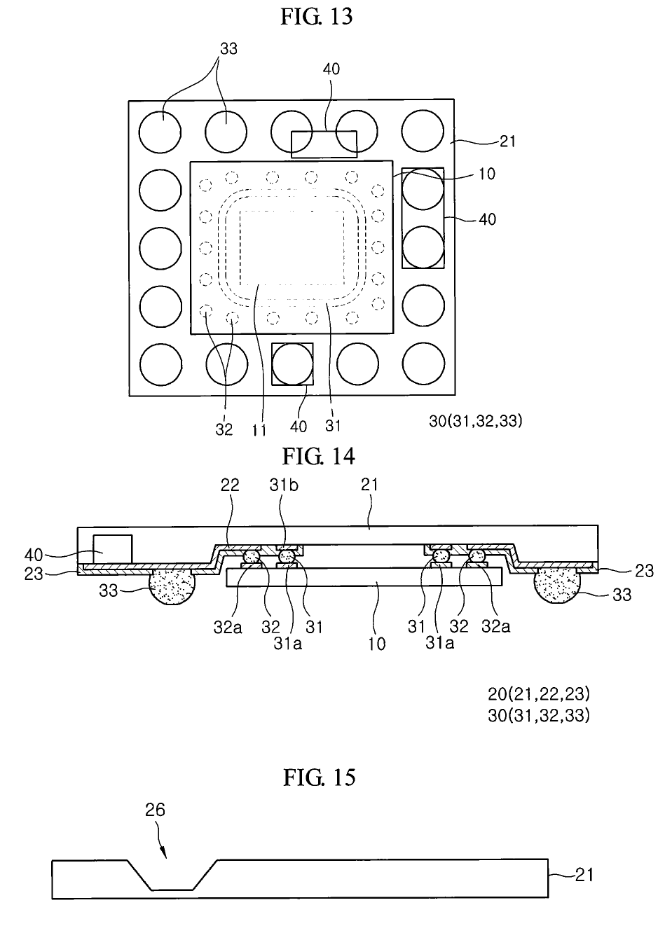

In the meantime, the passive device 40 may be mounted in one of various regions of the transparent substrate 21. For example, the passive device 40 may be mounted in a region corresponding to the single solder ball 33 as illustrated in FIG. 11, or the passive device 40 may be disposed between the photosensor chip 10 and a region that is between the two solder balls 33 as illustrated in FIG. 12. Although one passive device 40 is mounted according to the previous embodiments, the passive device 40 may be provided in triplicate in a photosensor package as illustrated in FIG. 13. That is, according to the present invention, at least one passive device 40 may be mounted in the transparent substrate 21 of the photosensor package.

In addition, referring to FIG. 14, a certain region disposed in the lower surface of the transparent substrate 21, preferably, a central portion may have a smaller thickness than that of the other portions, and the photosensor chip 10 may be mounted in the central portion. The thickness of the central portion of the transparent substrate 21 can be reduced through dry or wet etching. Herein, the step height between the etched portion and the un-etched portion may be steep or gentle. Meanwhile, the passive device 40 is mounted in the upper surface of the transparent substrate 21 on the outside of a pixel region, e.g., in the transparent substrate 21 on the outside of the solder ball 33. As such, since the photosensor chip 10 is mounted in the central portion that is thinner than the edge portion, the thickness of the photosensor chip 10 can be reduced, and thus, the thickness of a camera module can be reduced. In addition, the sizes of the solder balls 33 are determined according to the thickness of the photosensor chip 10, and the photosensor chip 10 is mounted in the central portion in which the thickness of the transparent substrate 21 is small. Accordingly, the solder balls 33 can be miniaturized, and thus, the photosensor package can be miniaturized.

A method of mounting the passive device 40 in the transparent substrate 21 according to the fifth embodiment as described above will now be described with reference to FIGS. 15 to 17.

Referring to FIG. 15, a certain region of the transparent substrate 21 is etched to form a recess 26 on which dry etching or wet etching may be performed. Preferably, the recess 26 is wider than a passive device to be mounted. Moreover, the recess 26 has a depth that is not excessively larger or smaller than the height of a passive device, and preferably, the recess 26 has a depth that is equal to the height of a passive device. The side wall of the recess 26 may have a gentle inclination. Even in this case, preferably, the bottom surface of the recess 26 is wider than a passive device. This is because, if the bottom surface of the recess 26 is narrower than a passive device, the passive device is hung on the side wall of the recess 26 without closely contacting the bottom surface of the recess 26, so that the passive device is unstably placed on the bottom surface of the recess 26.

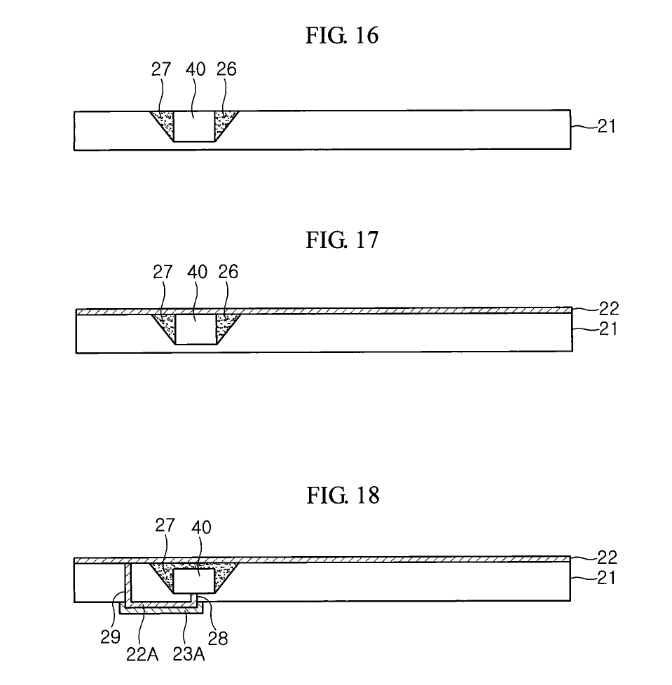

Referring to FIG. 16, the passive device 40 is mounted in the recess 26 formed in the transparent substrate 21. The passive device 40 is brought to contact the bottom surface of the recess 26, and thus, is stably placed on the bottom surface of the recess 26. An adhesive material may be applied to on a surface of the passive device 40 contacting the bottom surface of the recess 26 or to the bottom surface of the recess 26 such that the passive device 40 is stably placed on the bottom surface of the recess 26. Then, polymer 27 is formed in the rest space of the recess 26 in which the passive device 40 is placed, to fill the recess 26. At this point, the polymer 27 is formed out of an exposed surface of the passive device 40 to prevent a metal that will be formed later from being electrically insulated from the passive device 40 through the polymer 27. To this end, an etching process may be performed to remove the polymer 27 remaining on the transparent substrate 21 or the passive device 40 after the polymer 27 is formed, or a printing process is performed to form the polymer 27 only in a limited region.

Referring to FIG. 17, the metal line 22 is formed on the transparent substrate 21 including at least one portion on the passive device 40. The metal line 22 may be formed by forming a metal layer on the transparent substrate 21 by using a method such as sputtering or plating, and then, by patterning the metal layer through photo and etching processes. When a deposition process is performed through the sputtering using a shadow mask, the metal line 22 may be formed without photo and etching processes. Alternatively, the metal line 22 may be formed through a printing process. Also in this case, the metal line 22 may be formed without photo and etching processes.

Thereafter, a dielectric layer (not shown) used to expose a certain region of the metal line 22 is formed, and then, the metal line 22 may be attached to the photosensor chip through a connection part.

Alternatively, instead of directly connecting the metal line 22 formed on a surface of the transparent substrate 21 to the passive device 40, a second metal line 22A may be formed on another surface of the transparent substrate 21 and the inside of the transparent substrate 21 as illustrated in FIG. 18, so that the second metal line 22A can be connected to the passive device 40 and the metal line 22 through holes 28 and 29 in which a conductive material is buried. In this case, preferably, a dielectric layer 23A is formed on the second metal line 22A to prevent the second metal line 22A from being exposed to the outside. In addition, in this case, instead of exposing a surface of the passive device 40 out of the transparent substrate 21, the passive device 40 may be buried completely in the transparent substrate 21.

As described above, the photosensor package in accordance with another exemplary embodiment of the present invention includes the passive device 40 that may be mounted in the transparent substrate 21 of the substrate assembly 20, and preferably, be mounted coaxially with the solder ball 33. Therefore, it is possible to reduce the size of the printed circuit board according to the present invention compared to the conventional technology where a photosensor package and a passive device are mounted on the print circuit board, and thus it is also possible to reduce the size of the camera module. Moreover, according to the conventional technology, a signal path is extended by a long distance between the photosensor chip 10 and the passive device 40, and thus its electrical properties are deteriorated as noises flow into signals. However, since the passive device 40 is mounted on the substrate assembly 20 and disposed adjacent to the photosensor chip 10 in the inventive photosensor package, the signal path is shortened, and thus the electrical properties of the camera module are improved.

As described above, the photosensor package in accordance with the present invention includes the passive device disposed on an upper or lower side of the substrate assembly, wherein the photosensor chip is disposed on the lower side of the substrate assembly. In case the passive device is mounted at the lower side of the substrate assembly, the passive device may be mounted at the same axis as that of the plurality of solder balls or on the outside of the solder ball as being apart from the solder ball. Moreover, in case the passive device is mounted at the upper side of the substrate assembly, the passive device is formed to penetrate the upper and lower portions of the transparent substrate and connected to the metal line under the substrate assembly through the penetration hole where the conductive material is buried. Meanwhile, the substrate assembly where the passive device is built has a central portion whose thickness is smaller than those of the other portions so that the photosensor chip is disposed on the central portion.

In addition, the certain region of the substrate assembly in which the photosensor chip of the photosensor package in accordance with the present invention is mounted is etched to form the recess, and the passive device is mounted in the recess. The passive device may be mounted in the recess that is formed in the transparent substrate in the region where the solder ball is formed, or be buried in the region between the solder ball and the photosensor chip. That is, the passive device may be adjacent to the region in which the solder ball is formed.

In accordance with the exemplary embodiments of the present invention, since the passive device is mounted at the substrate assembly of the photosensor package, it is possible to reduce the size of the printed circuit board compared to the convention technology where the passive device is mounted at the print circuit board. That is, it is possible to reduce the area where the passive device is built and the area such as the width of the line connected to the passive device. Furthermore, since it is possible to reduce the distance between the photosensor chip and the passive device, the electrical properties are also improved. Moreover, since the building process can be simplified, the number of processes may be reduced compared to the convention technology. As a result, the weight of the camera module can be also reduced.

Although the deposition apparatus has been described with reference to the specific exemplary embodiments, it is not limited thereto. Therefore, it will be readily understood by those skilled in the art that various modifications and changes can be made thereto without departing from the spirit and scope of the present invention defined by the appended claims.

What is claimed is:

1. A photosensor package, comprising:
a substrate assembly;
a photosensor chip mounted at the substrate assembly;
a solder ball to electrically connect the photosensor chip, the substrate assembly and a printed circuit board; and
a passive device mounted at the substrate assembly.

2. The photosensor package of claim 1, wherein a thickness of one portion of the substrate assembly is smaller than those of other portions.

3. The photosensor package of claim 2, wherein the photosensor chip is mounted at the portion whose thickness is smaller.

4. The photosensor package of claim 1, wherein the passive device is mounted at the outside of a pixel region of the photosensor chip.

5. The photosensor package of claim 1, wherein the passive device is mounted at one side of the substrate assembly on which the photosensor chip is disposed.

6. The photosensor package of claim 5, wherein the passive device is mounted between the solder balls.

7. The photosensor package of claim 5, wherein the passive device is mounted at the outside of the solder ball.

8. The photosensor package of claim 1, wherein the passive device is mounted at the other side of the substrate assembly on which the photosensor chip is not disposed.

9. The photosensor package of claim 8, wherein the passive device is electrically connected to one side of the substrate assembly through a penetration hole which penetrates a portion of the substrate assembly and is filled with a conductive material.

10. A photosensor package, comprising:
a substrate assembly including a transparent substrate;
a photosensor chip mounted at the substrate assembly;
a plurality of solder balls to electrically connect the photosensor chip, the substrate assembly and a printed circuit board; and
a passive device mounted in the transparent substrate of the substrate assembly.

11. The photosensor package of claim 10, wherein a thickness of one portion of the substrate assembly is smaller than those of other portions.

12. The photosensor package of claim 11, wherein the photosensor chip is mounted at the portion whose thickness is smaller.

13. The photosensor package of claim 10, wherein the passive device is mounted at the outside of a pixel region of the photosensor chip.

14. The photosensor package of claim 13, wherein the passive device is mounted in a recess formed by etching the transparent substrate at a region corresponding to at least one of the solder balls.

15. The photosensor package of claim 13, wherein the passive device is mounted in a recess formed by etching the transparent substrate at a region between the solder ball and the photosensor chip.

16. The photosensor package of claim 13, wherein the passive device is mounted in a recess formed by etching the transparent substrate at the outside of the solder ball.

17. The photosensor package of claim 13, wherein the passive device is electrically connected through a metal line formed on a surface of the transparent substrate.

18. The photosensor package of claim 13, wherein the passive device is electrically connected to a surface of the transparent substrate through a through hole that vertically passes through a region of the transparent substrate, and a conductive material is buried in the through hole.
